(19) United States
(12) Patent Application Publication
(10) Pub. No.: US 2025/0233038 A1
(43) Pub. Date: Jul. 17, 2025

(54) SEMICONDUCTOR STRUCTURE AND MANUFACTURING METHOD THEREOF

(71) Applicant: United Microelectronics Corp., Hsinchu (TW)

(72) Inventors: Tsung-Yu Yang, Chiayi County (TW); Ming-Che Tsai, Tainan City (TW); Ping-Chia Shih, Tainan City (TW); Cheng-Tzung Tsai, Taipei City (TW); Yi Chun Teng, Taichung City (TW); Yi Chang Huang, Tainan City (TW)

(73) Assignee: United Microelectronics Corp., Hsinchu (TW)

(21) Appl. No.: 18/597,876

(22) Filed: Mar. 6, 2024

(30) Foreign Application Priority Data
Jan. 16, 2024 (TW) 113101651

(51) Int. Cl. H01L 23/367; H01L 21/74; H01L 23/00; H01L 23/373

(52) U.S. Cl. CPC H01L 23/367; H01L 21/74; H01L 23/3731; H01L 23/3732; H01L 23/3738; H01L 24/16; H01L 2224/16225

(57) ABSTRACT

A semiconductor structure including a substrate, an electronic component and an interconnection structure is provided. The substrate has a plurality of thermal vias, wherein the plurality of thermal vias penetrate the substrate. The electronic component is disposed on the substrate. The interconnection structure is disposed on the substrate and electrically connected to the electronic component. The plurality of thermal vias of the substrate are filled with a dielectric material, and a thermal conductivity of the dielectric material is greater than 200 W/m*K. A manufacturing method of a semiconductor structure is also provided.

### CROSS-REFERENCE TO RELATED APPLICATION

This application claims the priority benefit of Taiwan application serial no. 113101651, filed on Jan. 16, 2024. The entirety of the above-mentioned patent application is hereby incorporated by reference herein and made a part of specification.

### BACKGROUND

### Technical Field

The disclosure relates to a semiconductor structure and a manufacturing method thereof, and in particular to a semiconductor structure including a thermal via and a manufacturing method thereof.

### Description of Related Art

As the electronic components gradually develop in the direction of miniaturization and multi-functional integration, providing an efficient method for heat dissipation on the semiconductor wafer integrated with the electronic components is one of the development goals in the industry.

### SUMMARY

The disclosure provides a semiconductor structure having the improved heat dissipation effect.

According to some embodiments of the disclosure, a semiconductor structure including a substrate, an electronic component and an interconnection structure is provided. The substrate has a plurality of thermal vias, wherein the plurality of thermal vias penetrate the substrate. The electronic component is disposed on the substrate. The interconnection structure is disposed on the substrate and electrically connected to the electronic component. The plurality of thermal vias of the substrate are filled with a dielectric material, and a thermal conductivity of the dielectric material is greater than 200 W/m*K.

The disclosure also provides a manufacturing method of a semiconductor structure. The manufactured semiconductor structure has the improved heat dissipation effect.

According to another embodiments of the disclosure, the manufacturing method of the semiconductor structure includes the following steps. First, providing a semiconductor wafer, wherein the semiconductor wafer has a plurality of trenches located on a first surface of the semiconductor wafer. Next, filling the plurality of trenches with a dielectric material, wherein a thermal conductivity of the dielectric material is greater than 200 W/m*K. After that, forming an electronic component on the first surface of the semiconductor wafer. Then, forming an interconnection structure on the first surface of the semiconductor wafer, wherein the interconnection structure is electrically connected to the electronic component. After that, removing a portion of the semiconductor wafer until the dielectric material is exposed by a second surface of the semiconductor wafer, to form a plurality of thermal vias in the semiconductor wafer, wherein the second surface is opposite to the first surface.

Based on the above, the additional heat dissipation paths on the back side of the semiconductor structure are provided by forming the plurality of thermal vias in the substrate of the semiconductor structure. Therefore, the semiconductor structure provided by the disclosure could have improved heat dissipation effect. Furthermore, a material of the plurality of thermal vias of the semiconductor structure provided by the disclosure is the dielectric material, so the manufacturing cost of the plurality of thermal vias is relatively low when compared to that of the silicon vias filled with the metal material. In addition, the interference on the electrical connection between the thermal via and the electronic component could be reduced, and the pollution caused by the metal material could be avoided.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a partial cross-sectional schematic diagram of a semiconductor package structure according to an embodiment of the disclosure.

FIG. 1B is a partial cross-sectional schematic diagram of a semiconductor structure according to an embodiment of the disclosure.

FIG. 2 is a schematic flowchart of a manufacturing method of a semiconductor structure according to an embodiment of the disclosure.

FIG. 3A is a scanning electron microscope (SEM) image of a trench located in a central region of a semiconductor wafer according to an embodiment of the disclosure.

FIG. 3B is a SEM image of a trench located in an edge region of a semiconductor wafer according to an embodiment of the disclosure.

FIG. 3C is a SEM image of a trench located in a donut region (located between the central region and the edge region) of a semiconductor wafer according to an embodiment of the disclosure.

### DESCRIPTION OF THE EMBODIMENTS

The following examples are listed and described in detail with accompanying drawings, but the provided examples are not intended to limit the scope of the disclosure. In addition, the drawings are for illustrative purposes only and are not drawn to original size. To facilitate understanding, the same elements will be identified with the same symbols in the following description.

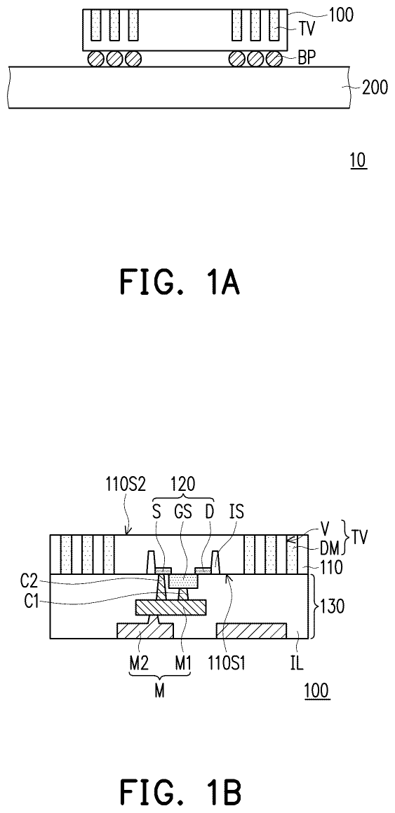

FIG. 1A is a partial cross-sectional schematic diagram of a semiconductor package structure according to an embodiment of the disclosure, and FIG. 1B is a partial cross-sectional schematic diagram of a semiconductor structure according to an embodiment of the disclosure.

Referring to FIG. 1A, which show a partial cross-sectional schematic diagram of a semiconductor package structure 10. The semiconductor package structure 10 could be a chip on wafer on substrate (CoWoS) package structure. For example, the semiconductor package structure 10 includes a semiconductor structure 100 and an interposer 200. The semiconductor structure 100 could be a semiconductor die, which could be a logic die, a power management integrated circuit die (PMIC die), a system on chip die (SoC die), or other suitable semiconductor die, but the disclosure is not limited thereto. Although only one semiconductor structure 100 is shown in FIG. 1A, the semiconductor package structure 10 of the present embodiment could include a plurality of the semiconductor structures 100, wherein the plurality of semiconductor structures 100 could be different or be the same semiconductor die from each other, and could be disposed on the interposer 200 at the same level to realize a 2.5D package structure in which the plurality of semiconductor structures 100 having different functions are arranged side by side horizontally. In some embodiments, the interposer 200 could be a silicon interposer, a glass interposer, or an organic interposer, but the disclosure is not limited thereto. For example, a plurality of micro-bump structures (u-bumps) BP are disposed on a surface of the interposer 200 facing the semiconductor structure 100, so that the plurality of semiconductor structures 100 could be bonded to the interposer 200.

In some embodiments, the semiconductor package structure 10 further includes a package substrate (not shown) on a side of the interposer 200 away from the semiconductor structure 100. The package substrate could be electrically connected to the interposer 200 through a plurality of bumps (not shown) located therebetween, and could be used to support the interposer 200 and the semiconductor structure 100. In some embodiments, the package substrate is a system-in-package substrate, but the disclosure is not limited thereto. In some embodiments, the semiconductor package structure 10 further includes a circuit

board (not shown) on a side of the package substrate away from the interposer 200. The circuit board could be electrically connected to the package substrate through a plurality of solder balls (not shown) located therebetween, and could be used to carry the package substrate. In some embodiments, the circuit board is a printed circuit board (PCB) having a ball grid array (BGA) structure, but the disclosure is not limited thereto.

Referring to FIG. 1B, which show a partial cross-sectional schematic diagram of the semiconductor structure 100. In the present embodiment, the semiconductor structure 100 includes a substrate 110, an electronic component 120 and an interconnection structure 130.

A material of the substrate 110 includes element semiconductors, compound semiconductors, alloy semiconductors or other suitable materials. For example, the material of the substrate 110 include silicon, but the disclosure is not limited thereto. In the present embodiment, the substrate 110 has a plurality of thermal vias TV, wherein the plurality of thermal vias TV penetrate the substrate 110. In detail, the substrate 110 has a first surface 110S1 and a second surface 110S2 opposite to the first surface 110S1, wherein the plurality of thermal vias TV penetrate the first surface 110S1 and the second surface 110S2. In the present embodiment, the plurality of thermal vias TV are filled with a dielectric material DM. In detail, one of the plurality of thermal vias TV could include a via V and the dielectric material DM, wherein the dielectric material DM fills the via V. In the present embodiment, a thermal conductivity of the dielectric material DM is greater than 200 W/m*K. For example, the dielectric material DM in the plurality of thermal vias TV includes aluminum nitride, beryllium oxide, silicon carbide, diamond, or a combination thereof, but the disclosure is not limited thereto. In some embodiments, a depth of the plurality of thermal vias TV could be about 50 microns (μm), but the disclosure is not limited thereto. In the present embodiment, the plurality of thermal vias TV are located on a back side of the semiconductor structure 100, so as to provide additional heat dissipation paths.

The electronic component 120 is disposed on the substrate 110. In the present embodiment, the electronic component 120 is disposed on the first surface 110S1 of the substrate 110. It is worth noting that although only one electronic component 120 is shown in FIG. 1B, the semiconductor structure 100 of the present embodiment could include a plurality of the electronic components 120. In some embodiments, the electronic component 120 include an active component, a passive component, or a combination thereof. In the present embodiment, the electronic component 120 includes a metal-oxide-semiconductor component, but the disclosure is not limited thereto. In detail, in some embodiments, the electronic component 120 includes a gate structure GS, a source S and a drain D. The gate structure GS includes a gate (not shown), a gate insulating layer (not shown), and a spacer (not shown), wherein the gate insulating layer is disposed between the gate and the substrate 110, and the spacer is disposed on both sides of the gate. The source S and the drain D are separated from each other, and are respectively disposed in the substrate 110 and located on both sides of the gate. In some embodiments, a plurality of isolation structures IS are also disposed in the substrate 110, and the electronic component 120 is located between the adjacent isolation structures IS. The plurality of isolation structures IS could include a suitable dielectric material to electrically isolate the adjacent electronic components 120 from each other. In the present embodiment, one of the plurality of isolation structures IS are disposed between the electronic component 120 and the plurality of thermal vias TV.

The interconnection structure 130 is disposed on the substrate 110, and is electrically connected to the electronic component 120. In the present embodiment, the interconnection structure 130 is disposed on the first surface 110S1 of the substrate 110 and includes a dielectric layer IL and an interconnection layer M.

The dielectric layer IL includes a multi-layer structure. In detail, the dielectric layer IL could include an interlayer dielectric layer (not shown) disposed on the first surface 110S1 of the substrate 110 and an inter-metal dielectric layer (not shown) disposed on the interlayer dielectric layer. In some embodiments, the interlayer dielectric layer and the inter-metal dielectric layer include suitable dielectric materials, but the disclosure is not limited thereto.

The interconnection layer M includes a first interconnection layer M1 and a second interconnection layer M2, wherein each of the first interconnection layer M1 and the second interconnection layer M2 could include wires, pads, vias, or a combination thereof. Materials of the first interconnection layer M1 and the second interconnection layer M2 include metal. For example, the materials of the first interconnection layer M1 and the second interconnection layer M2 include copper or copper alloy, but the disclosure is not limited thereto. In the present embodiment, the first interconnection layer M1 is closer to the substrate 110 than the second interconnection layer M2. In detail, the first interconnection layer M1 could be electrically connected to the gate structure GS and the source S through a contact window C1 and a contact window C2, respectively. The second interconnection layer M2 could be electrically connected to the first interconnection layer M1 through its conductive vias, but the disclosure is not limited thereto. It is worth noting that the interconnection layer M could also include other interconnection sub-layers except the first interconnection layer M1 and the second interconnection layer M2 in other embodiments, but the disclosure is not limited thereto.

Based on the above, since the semiconductor structure 100 of the present embodiment includes the plurality of thermal vias TV, there could be additional heat dissipation paths on the back side (the second surface 100S2) of the semiconductor structure 100, so that the efficiency of heat dissipation of the semiconductor structure 100 could be improved. In detail, the electronic component 120 and the interconnection structure 130 are disposed on the first surface 110S1 of the substrate 110, and the plurality of thermal vias TV are exposed by the second surface 110S2 of the substrate 110, so the heat generated by the electronic component 120 could be released from the second surface 110S2 of the substrate 110 through the plurality of thermal vias TV. Furthermore, the material filled in the plurality of thermal vias TV is the dielectric

material DM, so the manufacturing cost of the plurality of thermal vias TV is relatively low. In addition, the interference on the electrical connection between the plurality of thermal vias TV and the electronic component 120 (and/or other electronic components) could be reduced.

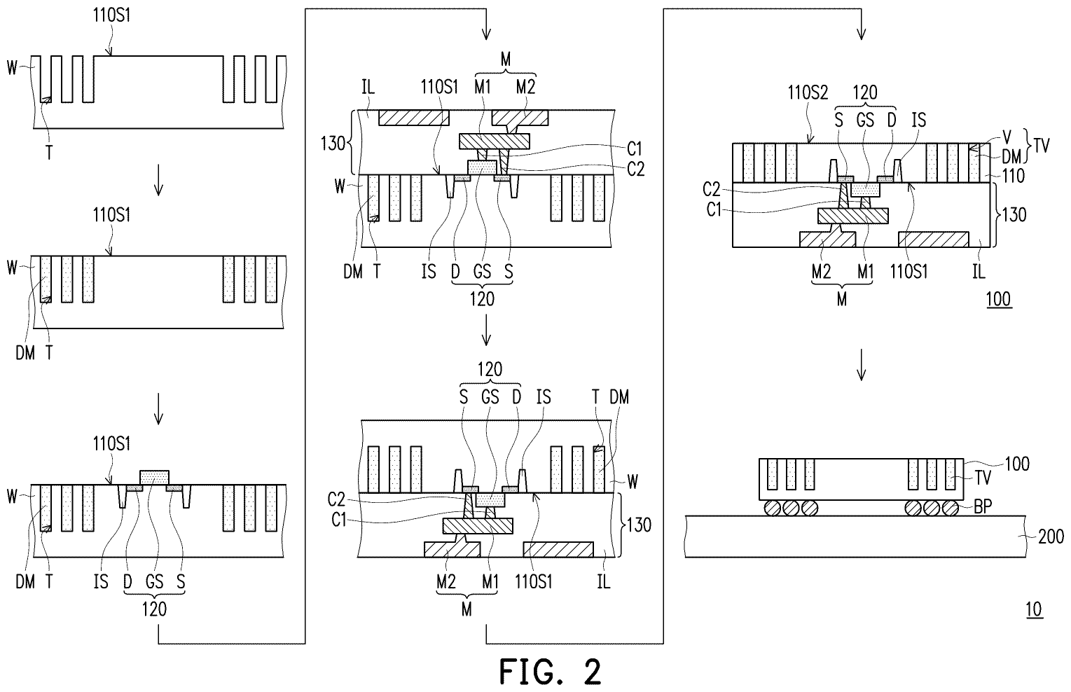

FIG. 2 is a schematic flowchart of a manufacturing method of a semiconductor structure according to an embodiment of the disclosure. It should be noted that the embodiment of FIG. 2 could use the reference numbers and portions of the content of the above embodiments of FIGS. 1A and 1B, wherein the same or similar reference numbers are used to represent the same or similar elements, and descriptions of the same technical contents are omitted.

First, providing a semiconductor wafer W including a plurality of semiconductor dies to be cut. In the present embodiment, a first surface 110S1 of the semiconductor wafer W has a plurality of trenches T. The plurality of trenches T could be formed by performing a photolithography process and an etching process or other suitable processes on the semiconductor wafer W, but the disclosure is not limited thereto. In some embodiments, a depth of the plurality of trenches T could be about 50 microns (μm), but the disclosure is not limited thereto.

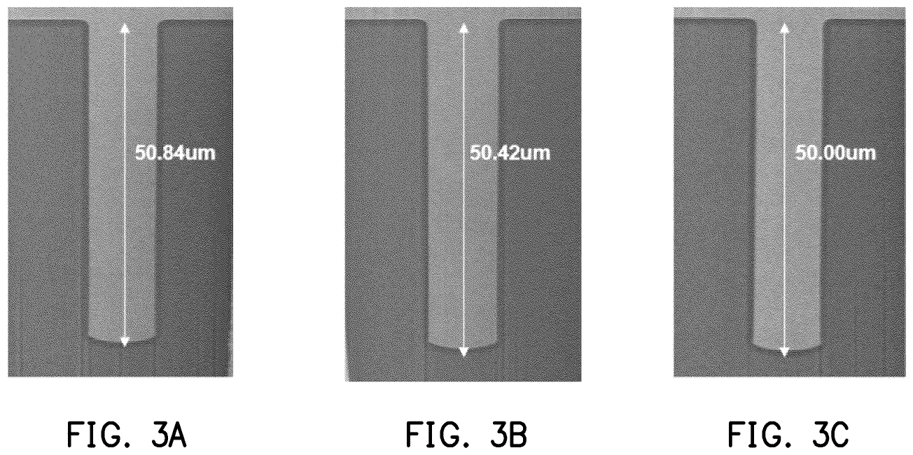

Referring to FIGS. 3A to 3C, which each show a scanning electron microscope (SEM) image of the plurality of trenches T in a central region, an edge region and a donut region of the semiconductor wafer W. As shown in FIGS. 3A to 3C, the plurality of trenches T in the central region of the semiconductor wafer W have a depth of 50.84 μm, the plurality of trenches T in the edge region of the semiconductor wafer W have a depth of 50.42 μm, and the plurality of trenches T in the donut region of the semiconductor wafer W have a depth of 50.00 μm. The SEM images show that the plurality of trenches T formed in each area of the semiconductor wafer W could have the similar size and have a relatively good yield.

It is worth noting that the rest of the introduction pertaining the semiconductor wafer W could refer to the above embodiments pertaining the substrate 110, and would be omitted herein. Next, filling the plurality of trenches T with a dielectric material DM, wherein a thermal

conductivity of the dielectric material DM is greater than 200 W/m*K. The step of filling the plurality of trenches T with the dielectric material DM could be performed by performing the following process, but the disclosure is not limited thereto. First, performing a deposition process or other suitable process to form a dielectric material layer (not shown) on the first surface 110S1 of the semiconductor wafer W, wherein the dielectric material layer fills the plurality of trenches

T. Next, performing a planarization process to remove the dielectric material layer formed on the first surface 110S1 of the semiconductor wafer W and located outside the plurality of trenches T, so that the dielectric material DM formed in the plurality of trenches T and the first surface 110S1 of the semiconductor wafer W could be substantially at the same level. It is worth noting that the rest of the introduction pertaining the dielectric material DM could refer to the above embodiments, and would be omitted herein.

Afterwards, forming an electronic component 120 on the first surface 110S1 of the semiconductor wafer W. The electronic component 120 could be formed in a front-end-of-line (FEOL) process of the semiconductor structure 100 of the present embodiment. The electronic component 120 could include an active component, a passive components, or a combination thereof, but the disclosure is not limited thereto. It is worth noting that the rest of the introduction pertaining the electronic component 120 could refer to the above embodiments, and would be omitted herein.

Next, forming an interconnection structure 130 on the first surface 110S1 of the semiconductor wafer W, wherein the interconnection structure 130 is electrically connected to the electronic component 120. The interconnection structure 130 includes a dielectric layer IL and an interconnection layer M, and could be formed in a back-end-of-line (BEOL) process of the semiconductor structure 100 of the present embodiment. In some embodiments, the dielectric layer IL could be formed by performing a chemical vapor deposition process or other suitable processes, and the interconnection layer M could be formed by performing an electroplating process or other suitable processes, but the disclosure is not limited thereto. It is worth noting that the rest of the introduction pertaining the interconnection structure 130 could refer to the above embodiments, and would be omitted herein.

Then, removing a portion of the semiconductor wafer W to form a plurality of thermal vias TV. Specifically, in the present embodiment, after the semiconductor wafer W is turned over, performing a planarization process on the semiconductor wafer W to remove the portion of the semiconductor wafer W. The planarization process could be a chemical mechanical planarization process, but the disclosure is not limited thereto. In the present embodiment, removing the portion of the semiconductor wafer W until the dielectric material DM is exposed, wherein the dielectric material DM disposed in the plurality of trenches T could serve as a termination layer. In some embodiments, a portion of the dielectric material DM may be removed during the planarization process. After performing the planarization process, the dielectric material DM is exposed by a second surface 110S2 (opposite to the first surface 110S1) of the semiconductor wafer W. In other words, the plurality of original trenches T formed in the semiconductor wafer W are transformed into a plurality of vias V penetrating the semiconductor wafer W. It is worth noting that the rest of the introduction pertaining the plurality of thermal vias TV could refer to the above embodiments, and would be omitted herein.

Afterwards, dicing the semiconductor wafer W to form a plurality of the semiconductor structures 100. The step of dicing the semiconductor wafer W could be performed by performing the following process, but the disclosure is not limited thereto. First, placing the semiconductor wafer W on a dicing tape (not shown). Next, dicing the semiconductor wafer W by a wafer dicing device (not shown) to form the plurality of semiconductor structures 100. Afterwards, performing a suitable separation process to separate the plurality of semiconductor structures 100 from the dicing tape. It is worth noting that the rest of the introduction pertaining the semiconductor structure 100 could refer to the above embodiments, and would be omitted herein.

It is worth noting that at least one semiconductor structures 100 could be subsequently bonded to the interposer 200 through a plurality of micro-bump structures BP to form a semiconductor package structure 10, but the disclosure is not limited thereto. It is worth noting that the introduction pertaining the interposer layer 200 could refer to the above embodiments, and would be omitted herein. In addition, in some embodiments, a side of the interposer 200 away from the semiconductor structure 100 could also include the package substrate and the circuit board described in above embodiments, but the disclosure is not limited thereto.

At this point, the manufacturing method of the semiconductor structure 100 is completed. Although the manufacturing method of the semiconductor structure 100 in the present embodiment is described by taking the above method as an example, the manufacturing method of the semiconductor structure provided by the disclosure is not limited thereto.

For example, in the manufacturing method of the semiconductor structure 100 provided by other embodiments of the disclosure, the step of forming the plurality of trenches T and filling the plurality of trenches T with the dielectric material DM could be performed after the step of forming the interconnection structure 130.

In detail, the manufacturing method of the semiconductor structure 100 provided by other embodiments of the disclosure could include performing the following steps. First, providing a semiconductor wafer W. Next, forming an electronic component 120 on a first surface 110S1 of the semiconductor wafer W. After that, forming an interconnection structure 130 on the first surface 110S1 of the semiconductor wafer W, wherein the interconnection structure 130 is electrically connected to the electronic component 120. Then, turning over the semiconductor wafer W, and removing a portion of the semiconductor wafer W to form a plurality of vias V located on a second surface 110S2 of the semiconductor wafer W. After that, filling the plurality of vias V with a dielectric material DM to form a plurality of thermal vias TV, wherein a thermal conductivity of the dielectric material DM is greater than 200 W/m*K.

In summary, in the semiconductor structure and the manufacturing method thereof provided by the disclosure, the additional heat dissipation paths on the back side of the semiconductor structure are provided by forming the plurality of thermal vias in the substrate of the semiconductor structure. Therefore, the semiconductor structure provided by the disclosure could have improved heat dissipation effect. Furthermore, the material of the plurality of thermal vias of the semiconductor structure provided by the disclosure is the dielectric material, so the manufacturing cost of the plurality of thermal vias is relatively low when compared to that of the silicon vias filled with the metal material. In addition, the interference on the electrical connection between the thermal via and the electronic component could be reduced, and the pollution caused by the metal material could be avoided.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, including:
a substrate, having a plurality of thermal vias, wherein the plurality of thermal vias penetrate the substrate;
an electronic component, disposed on the substrate; and
an interconnection structure, disposed on the substrate and electrically connected to the electronic component,
wherein the plurality of thermal vias of the substrate are filled with a dielectric material, and a thermal conductivity of the dielectric material is greater than 200 W/m*K.

2. The semiconductor structure according to claim 1, wherein the dielectric material includes aluminum nitride, beryllium oxide, silicon carbide, diamond, or a combination thereof.

3. The semiconductor structure according to claim 1, wherein the electronic component and the interconnection structure are disposed on a first surface of the substrate, and the plurality of thermal vias are exposed by a second surface of the substrate, wherein the second surface is opposite to the first surface.

4. The semiconductor structure according to claim 1, including at least one semiconductor dies.

5. A manufacturing method of a semiconductor structure, including:
providing a semiconductor wafer, wherein the semiconductor wafer has a plurality of trenches located on a first surface of the semiconductor wafer;
filling a dielectric material in the plurality of trenches, wherein a thermal conductivity of the dielectric material is greater than 200 W/m*K;
forming an electronic component on the first surface of the semiconductor wafer;
forming an interconnection structure on the first surface of the semiconductor wafer, wherein the interconnection structure is electrically connected to the electronic component; and
removing a portion of the semiconductor wafer until the dielectric material is exposed by a second surface of the semiconductor wafer, to form a plurality of thermal vias in the semiconductor wafer, wherein the second surface is opposite to the first surface.

6. The manufacturing method of the semiconductor structure according to claim 5, further including following steps after forming the plurality of thermal vias:
dicing the semiconductor wafer to form a plurality of the semiconductor structures.

7. The manufacturing method of the semiconductor structure according to claim 5, wherein removing the portion of the semiconductor wafer includes performing a chemical mechanical planarization process on the second surface of the semiconductor wafer.

8. The manufacturing method of the semiconductor structure according to claim 5, wherein the dielectric material includes aluminum nitride, beryllium oxide, silicon carbide, diamond, or a combination thereof.

9. The manufacturing method of the semiconductor structure according to claim 5, wherein the semiconductor structure includes at least one semiconductor dies.

10. A manufacturing method of a semiconductor structure, including:
providing a semiconductor wafer;
forming an electronic component on a first surface of the semiconductor wafer;
forming an interconnection structure on the first surface of the semiconductor wafer, wherein the interconnection structure is electrically connected to the electronic component;
removing a portion of the semiconductor wafer to form a plurality of vias located on a second surface of the semiconductor wafer, wherein the second surface is opposite to the first surface; and
filling the plurality of vias with a dielectric material to form a plurality of thermal vias, wherein a thermal conductivity of the dielectric material is greater than 200 W/m*K.
